(19) United States
(12) Patent Application Publication
(10) Pub. No.: US 2015/0179740 A1
(43) Pub. Date: Jun. 25, 2015

(54) TRANSISTOR DEVICE WITH STRAINED LAYER

(71) Applicant: GLOBAL FOUNDRIES Inc., Grand Kayman (KY)

(72) Inventors: Dina H. Triyoso, Dresden (DE); Elke Erben, Dresden (DE); Martin Trentzsch, Radebeul (DE); Peter Moll, Dresden (DE); Roman Boschke, Dresden (DE)

(73) Assignee: GLOBAL FOUNDRIES Inc., Grand Kayman (KY)

(21) Appl. No.: 14/136,420

(22) Filed: Dec. 20, 2013

(51) Int. Cl. H01L 29/10; H01L 29/66; H01L 29/78

(52) U.S. Cl. CPC H01L 29/1054; H01L 29/7843; H01L 29/66477

(57) ABSTRACT

A method for forming a transistor device is disclosed that includes forming a first gate electrode on a substrate, forming a nitride layer, in particular an SiN layer, over the first gate electrode and forming a first strained layer over the nitride layer, in particular the SiN layer. A transistor device is also disclosed that includes a first gate electrode, a nitride layer, in particular an SiN layer, formed over the first gate electrode and a first strained layer formed over the nitride layer, in particular the SiN layer.

### BACKGROUND OF THE INVENTION

1. Field of the Invention

Generally, the present disclosure relates to the field of the manufacture of integrated circuits and semiconductor devices, and, more particularly, to FETs comprising strained layers for improving the mobility of charge carriers in the channel regions.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer.

A field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on, among other things, the dopant concentration, the mobility of the majority charge carriers and, for a given extension of the channel region in the transistor width direction, the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the reduction of the channel length, and associated therewith the reduction of the channel resistivity, renders the channel length a dominant design criteria for accomplishing an increase in the operating speed of the integrated circuits.

The shrinkage of the transistor dimensions, however, involves a plurality of issues associated therewith that have to be addressed so as to not unduly offset the advantages obtained by steadily decreasing the channel length of MOS transistors. One issue associated with reduced gate lengths is the occurrence of so-called short channel effects, which may result in a reduced controllability of the channel conductivity. Short channel effects may be countered by certain design techniques, some of which, however, may be accompanied by a reduction of the channel conductivity, thereby partially offsetting the advantages obtained by the reduction of critical dimensions.

In view of this situation, it has been proposed to enhance device performance of the transistor elements not only by reducing the transistor dimensions but also by increasing the charge carrier mobility in the channel region for a given channel length, thereby increasing the drive current capability and thus transistor performance. For example, the lattice structure in the channel region may be modified, for instance by creating tensile or compressive strain therein, which results in a modified mobility for electrons and holes, respectively. For example, creating tensile strain in the channel region of a silicon layer having a standard crystallographic configuration may increase the mobility of electrons, which, in turn, may directly translate into a corresponding increase of the conductivity of N-type transistors. On the other hand, compressive strain in the channel region may increase the mobility of holes, thereby providing the potential for enhancing the performance of P-type transistors.

One promising approach in this respect is a technique that enables the creation of desired stress conditions within the channel region of different transistor elements by adjusting the stress characteristics of a contact etch stop layer that is formed above the basic transistor structure in order to form contact openings to the gate and drain and source terminals in an interlayer dielectric material. The effective control of mechanical stress in the channel region, i.e., effective stress engineering, may be accomplished by individually adjusting the internal stress in the contact etch stop layer of the respective transistor in order to position a contact etch contact layer having an internal compressive stress above a P-channel transistor while positioning a contact etch stop layer having an internal tensile strain above an N-channel transistor, thereby creating compressive and tensile strain, respectively, in the respective channel regions.

Typically, the contact etch stop layer is formed by plasma enhanced chemical vapor deposition processes (PECVD) above the transistor, i.e., above the gate structure and the drain and source regions, wherein, for instance, silicon nitride may be used due to its high etch selectivity with respect to silicon dioxide, which is a well-established interlayer dielectric material. Furthermore, PECVD silicon nitride may be deposited with a high intrinsic stress, for example, up to 2 Giga Pascal (GPa) or significantly higher of compressive stress and up to 1 GPa and significantly higher of tensile stress, wherein the type and the magnitude of the intrinsic stress may be efficiently adjusted by selecting appropriate deposition parameters. For example, ion bombardment, deposition pressure, substrate temperature, gas components and the like represent respective parameters that may be used for obtaining the desired intrinsic stress.

FIG. 1 shows an example of a transistor of the art. The transistor comprises a gate dielectric 1, a gate electrode 2 and sidewall spacers 3. The gate dielectric 1 separates the gate electrode 2 from a corresponding channel region formed in a semiconductor substrate. Moreover, source/drain regions 4 are formed in the semiconductor substrate. Furthermore, a stress-inducing layer 5 is formed over the gate electrode 2 and sidewall spacers 3. Critical dimensions, such as the gate length, i.e., the horizontal extension of the gate electrode 2, may be approximately 50 nm or significantly less. The stress-inducing layer 5 may be a silicon nitride layer comprising a high compressive or tensile stress to enhance the mobility of charge carriers in the channel region below the gate electrode 2 and gate dielectric 1. A silicon dioxide layer (not shown) may be formed on the stress-inducing layer 5.

However, particularly in the context of high-k/metal gate PFETs, reliability is heavily affected by bias temperature instability and hot carrier injection. Thus, in spite of the recent engineering process, there is a need for an improved mechanism for enhancing the mobility of charge carriers in transistor channels.

In view of the situation described above, the present disclosure provides techniques for the manufacture of a transistor, particularly comprising high-k/metal gate structures, wherein a thin SiN layer is formed on the gate electrode of the transistor and a strained layer is formed on the SiN layer.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method for forming a transistor device includes the steps of forming a first gate electrode on a substrate, forming a thin nitride layer (layer comprising nitride), in particular, a thin SiN layer, over the first gate electrode and forming a first strained layer (stress-inducing layer) over the thin nitride layer, in particular, the thin SiN layer. Also disclosed is a transistor device including a first gate electrode, a thin nitride layer, in particular, a thin SiN layer, formed over the first gate electrode and a first strained layer formed over the thin nitride layer, in particular, the thin SiN layer.

There are two types of strained layers (stress-inducing layers), namely layers showing compressive strain or tensile strain, that may be formed as the first strained layer. A compressively strained layer may be formed on a P-channel FET, whereas a layer showing tensile strain may be formed on an N-channel FET. According to one example, the method also includes the steps of forming a second gate electrode on the substrate and forming a second strained layer over the second gate electrode, wherein the strain of the second strained layer is different in type from the strain of the first strained layer and wherein the first strained layer is formed over the second strained layer. The nitride layer or SiN layer may be formed directly on the first gate electrode or directly on a cap layer formed on the first gate electrode. In addition, the nitride layer or SiN layer may be formed on the second strained layer.

Moreover, a semiconductor device is disclosed including a first transistor device comprising a first gate electrode, a thin nitride layer, in particular, a thin SiN layer, formed over the first gate electrode and a first strained layer formed over the thin nitride layer, in particular, the thin SiN layer, and further including a second transistor device, wherein the first strained layer is formed over a second strained layer that is formed over the second transistor device but not over the first transistor device and wherein the strain of the second strained layer is different in type from the strain of the first strained layer.

In all of the above-mentioned examples, the thin nitride layer or SiN layer may have a thickness of below 3 nm, particularly, below 2 nm, and at least 1 nm. Moreover, the thin nitride layer or SiN layer may be formed by atomic layer deposition, in particular, plasma enhanced atomic layer deposition. The above-mentioned first and/or second strained layer may comprise a nitride material and may be formed of SiN.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a transistor device of the art that comprises a strained layer formed over the gate electrode and sidewall spacers of the transistor device;

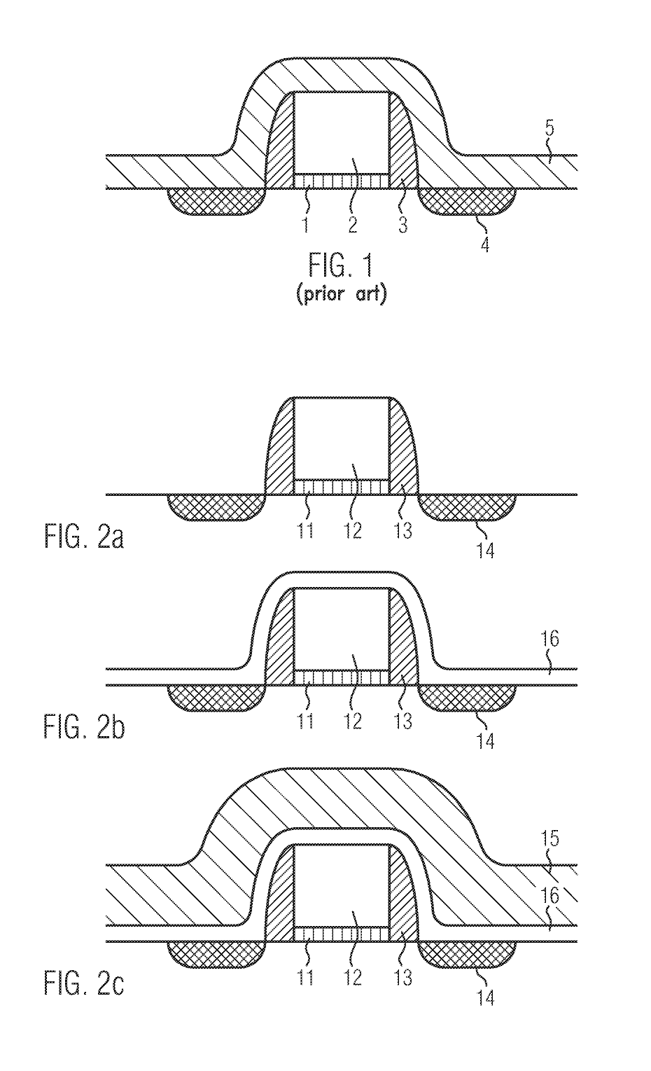

FIGS. 2a-2c show different manufacturing stages for the production of a transistor device according to an example of the present invention; and

FIGS. 3a-3d show different manufacturing stages for the production of a semiconductor device comprising two transistor devices according to an example of the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, e.g., NMOS, PMOS, CMOS, etc., and is readily applicable to a variety of devices, including, but not limited to, logic devices, memory devices, etc.

The present disclosure provides transistor devices and methods for the manufacture of the same. A transistor device according to one example of the present invention comprises a thin nitride layer or SiN layer formed over the gate electrode of the transistor. The strained layer may comprise or consist of nitride, for example, the strained layer may be an SiN layer. By providing the thin nitride layer or thin SiN layer between the gate electrode and a strained layer comprising compressive stress, the bias temperature instability and hot carrier injection deteriorating operation of a P-channel MOSFET in the art may be significantly suppressed. Moreover, using nitride material or SiN material for the thin layer between the gate electrode and the strained layer comprising or consisting of nitride, low fringe capacitance and high compatibility with current strain technologies may be provided.

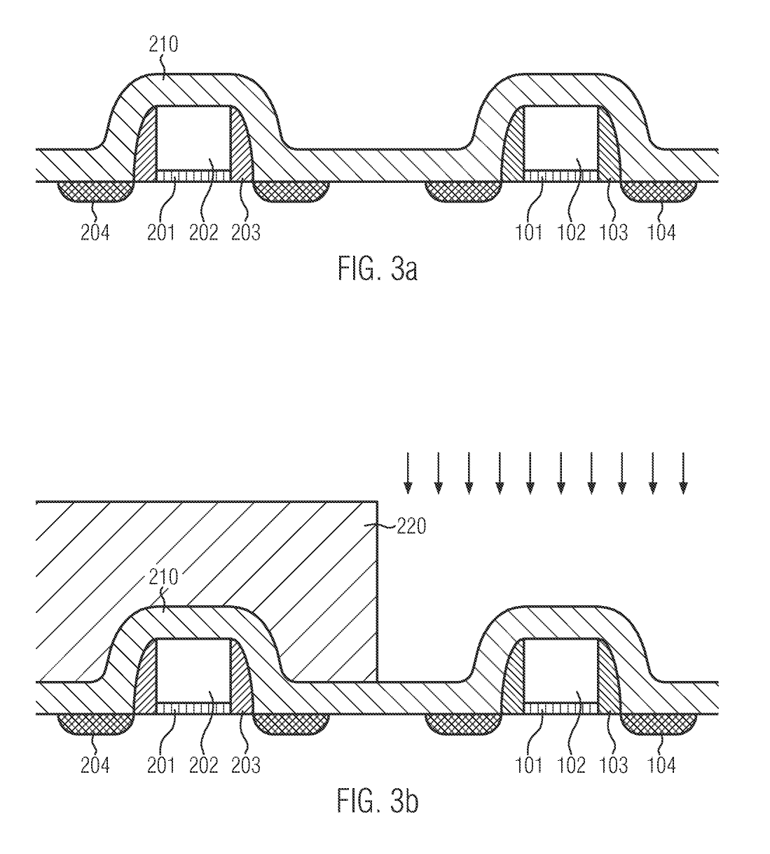

FIGS. 2a-2c illustrate an example for the production of an inventive transistor device. FIG. 2a shows a gate dielectric 11 formed on a semiconductor substrate. The semiconductor substrate may comprise a semiconductor layer, which in turn may be comprised of any appropriate semiconductor material, such as silicon, silicon/germanium, silicon/carbon, other II-VI or III-V semiconductor compounds and the like. The semiconductor layer may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon and the like. Furthermore, the substrate and the semiconductor layer may define an SOI (silicon-on-insulator) configuration. The semiconductor substrate may be a silicon substrate, in particular, a single crystal silicon substrate. Other materials may be used to form the semiconductor substrate such as, for example, germanium, silicon/germanium, gallium phosphate, gallium arsenide, etc.

A gate electrode 12 is formed on the gate dielectric 11. Moreover, as shown in FIG. 2a, sidewall spacers 13 that may consist of SiN and source/drain regions 14 are formed. The drain and source regions 14 may be formed in combination with the sidewall spacer structures 13 on the basis of well-established deposition, anisotropic etch processes and implantation sequences in order to establish the desired vertical and lateral dopant profiles.

In sophisticated transistor elements, a plurality of features finally determine the overall performance of the transistor, wherein a complex mutual interaction of these factors may be difficult to assess such that a wide variety of performance variations may be observed for a given basic transistor configuration. For example, the conductivity of doped silicon-based semiconductor regions representing the source/drain regions 14 may be increased by providing a metal silicide therein in order to reduce overall sheet resistance and contact resistivity. For example, the drain and source regions may receive a metal silicide, such as nickel silicide, nickel platinum silicide and the like, thereby reducing the overall series resistance of the conductive path between the drain and source terminals and the intermediate channel region. Similarly, a metal silicide may typically be formed in the gate electrode 12, which may comprise polysilicon material, thereby enhancing conductivity and thus reducing signal propagation delay. Although an increased amount of metal silicide in the gate electrode may per se be desirable in view of reducing the overall resistance thereof, a substantially complete silicidation (salicidation) of the polycrystalline silicon material down to the gate dielectric material may not be desirable in view of threshold voltage adjustment of the corresponding transistor element. It may, therefore, be desirable to maintain a certain portion of the doped polysilicon material in direct contact with the gate dielectric material so as to provide well-defined electronic characteristics in the channel region, so as to avoid significant threshold variations, which may be caused by a substantially full silicidation within portions of the gate electrode 12.

Formation of the gate electrode 12 may comprise depositing polycrystalline silicon on the gate dielectric material by low pressure chemical vapor deposition and gate etching as known in the art. Particularly, for transistor devices with very short channel lengths, for example, of some 50 nm or below, gate structures with high-k dielectric gate insulating layers and one or more metal layers and a polysilicon layer functioning as a gate electrode have been provided that show improved operational characteristics as compared to conventional silicon dioxide/polysilicon gates. The high-k isolation layers may include or consist of tantalum oxide, hafnium oxide, titanium oxide or hafnium silicates, for example.

There are basically two well-known processing methods for forming a planar or 3D transistor with a high-k/metal gate structure: the so-called “gate last” or “replacement gate” technique and the so-called “gate first” technique. In the replacement gate technique, a so-called “dummy” or sacrificial gate structure is initially formed and remains in place as many process operations are performed to form the device, for example, the formation of doped source/drain regions, performing an anneal process to repair damage to the substrate caused by the ion implantation processes and to activate the implanted dopant materials. At some point in the process flow, the sacrificial gate structure is removed to define a gate cavity where the final high-k/metal gate structure for the device is formed. Using the “gate first” technique, on the other hand, involves forming a stack of layers of material across the substrate, wherein the stack of materials includes a high-k gate isolation layer, one or more metal layers, a layer of polysilicon and a protective cap layer, for example, silicon nitride. One or more etching processes are performed to pattern the stack of materials to thereby define the basic gate structures for the transistor devices. Thus, a high-k/metal gate structure may be formed by layers 11 and 12 of FIG. 2a.

As shown in FIG. 2b a thin SiN layer 16 is formed over the entire structure comprising the gate electrode 12 and sidewall spacers 13. It is noted that, in the following description, reference is made to a thin SiN layer 16, for example. However, it is envisaged that any layer comprising nitride can be used instead, in principle. The SiN layer 16 may have a thickness of between 1-3 nm, for example, below 2 nm. The SiN layer 16 may be formed by atomic layer deposition, in particular, plasma enhanced atomic layer deposition. Plasma enhanced atomic layer deposition allows for excellent thickness control of the thin SiN layer 16 and provides for a highly conformal deposition. In particular, the excellent conformality allows formation of the SiN even in the context of advanced 28-nm technology. Plasma enhanced atomic layer deposition uses chemical precursors just like in thermal atomic layer deposition but it also cycles an RF-plasma creating the necessary chemical reactions in a highly controlled manner. By the introduction of a low temperature plasma step in the atomic layer deposition reaction cycle, it is possible to deliver additional reactivity to the surface in the form of plasma-produced species. This opens up a processing parameter space that is unattainable by merely thermally-driven processes.

As shown in FIG. 2c, a strained layer 15 is formed on the thin SiN layer 16. For example, the strained layer 15 exhibits compressive stress in order to provide an enhanced mobility of charge carriers in a P-channel transistor device. The strained layer 15 may, for example, be a nitride (contact etch stop) layer, in particular, an SiN layer. During the deposition of the silicon nitride material, respective process parameters, such as composition of carrier gases and reactive gases, substrate temperature, deposition pressure and, in particular, ion bombardment during the deposition may significantly influence the finally obtained intrinsic stress of the material as deposited with respect to the underlying materials. In any case, the SiN layer 16 prevents diffusion of hydrogen that may be present in the strained layer 15 to the channel region of the transistor.

After formation of the strained layer 15, a silicon dioxide liner may be formed thereabove and an interlayer dielectric material, such as a silicon dioxide material, may be formed on the interlayer dielectric material, followed by a patterned resist mask in order to define respective openings for forming a contact opening in the interlayer dielectric material.

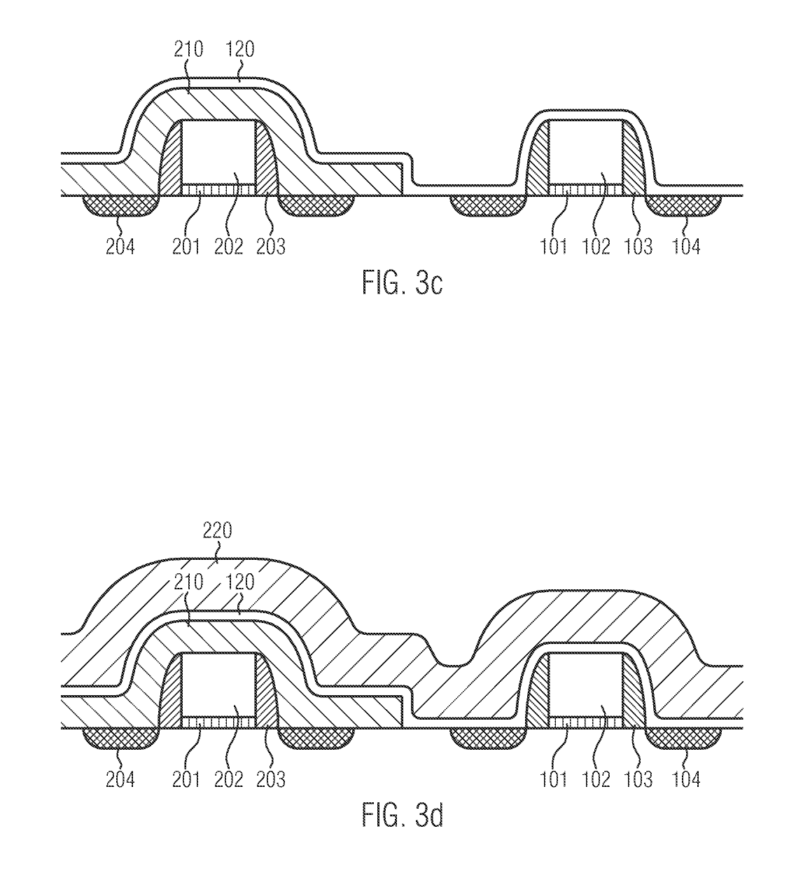

FIGS. 3a-3d show another example of the herein provided method for the manufacture of a semiconductor device. As shown in FIG. 3a, an N-channel transistor comprising a gate dielectric 201, a gate electrode 202, sidewall spacers 203 and source/drain regions 204 is formed on a semiconductor substrate. Moreover, a P-channel transistor comprising a gate dielectric 101, a gate electrode 102, sidewall spacers 103 and source/drain regions 104 is formed on the semiconductor substrate. The semiconductor substrate may be similar to the one described above with reference to FIGS. 2a-2c.

It should be noted that the source/drain regions 104 of the P-channel transistor may be formed in the form of elevated source/drain regions. As transistor dimensions approached 1μ, the conventional contact structures began to limit device performance in several ways. First, it was not possible to minimize the contact resistance, if the contact hole was also of minimum size, and problems with cleaning the small contact holes became a concern. In addition, the area of the source/drain regions 104 could not be minimized because the contact hole had to be aligned to these regions with a separate masking step, and extra area had to be allocated for misalignment, however, the extra area resulted in increased source/drain-to-substrate junction capacitance, which decreased the speed of the device. When non-minimum-width MOSFETs were manufactured with conventional contacts, several small, uniform sized contact holes were usually used rather than one wider contact hole. The problem with using several small, equally sized contact holes rather than one wider one, was that the full width of the source/drain region was thus not available for the contact structure. As a result, the device contact resistance was proportionally larger than it would have been in a device having minimum width. An elevated source/drain structure obtained by selectively depositing silicon onto the exposed source/drain regions are helpful for alleviating the problem related to the contact resistance.

As also shown in FIG. 3a, a strained layer 210 is formed over the entire structure comprising the N-channel and P-channel transistors. In the shown example, the strained layer 210 exhibits tensile stress in order to enhance the mobility charge in the channel region of the N-channel transistor. The strained layer 210 may comprise a nitride material, in particular, the strained layer may consist of SiN. Next, a patterned mask layer 220 is formed over the N-channel transistor as shown in FIG. 3b. The patterned mask layer 220 may be formed from a photoresist layer after exposing and patterning as known in the art. The strained layer 210 is removed from the regions exposed by the patterned mask layer 220 (see FIG. 3c). Removal of the strained layer 210 may comprise wet or dry etching.

After stripping of the patterned mask layer 220, a thin SiN layer 120 is formed over the resulting structure. The thin SiN layer 120 is formed on the remaining strained layer 210, on the semiconductor substrate between the transistors where the strained layer 210 has been removed, on the sidewall spacers 103 of the P-channel transistor and the gate electrode 102 of the P-channel transistor. Moreover, the thin SiN layer 120 is formed on the source/drain regions 104. If elevated source/drain regions are provided, the thin SiN layer 120 may be formed in a very conformal manner on the elevated source/drain regions. According to the shown example, the thin SiN layer 120 is formed by plasma enhanced atomic layer deposition. The thickness of the thin SiN layer 120 is below 3 nm, in particular, below 2 nm.

After formation of the thin SiN layer 120, a compressively strained layer 220 is formed on the thin SiN layer 120. The compressively strained layer 220 provides enhanced mobility of charge carriers in the channel region of the P-channel transistor below the gate dielectric 101 and gate electrode 102.

In all of the above-described examples, the strained layers may be formed by plasma enhanced chemical vapor deposition with a stress level of at least 500 MPa or at least 1 GPa, for example. The thicknesses of the strained layers may be more than some hundred nm.

As a result, the present disclosure provides manufacturing techniques for semiconductor devices comprising strained layers for enhancing the mobility of charge carriers in the channels of FETs. According to the invention, a thin SiN layer is formed between the strained layer and the gate electrode of a transistor. As a result, the bias temperature instability and hot carrier injection that cause degradation of the reliability of FETs of the art can be suppressed.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method for forming a transistor device, comprising
forming a first gate electrode on a substrate;
forming a nitride layer over said first gate electrode; and
forming a first strained layer over said nitride layer.

2. The method of claim 1, wherein said nitride layer is an SiN layer.

3. The method of claim 1, wherein said nitride layer has a thickness of less than 3 nm.

4. The method of claim 1, wherein said first strained layer comprises silicon nitride.

5. The method of claim 1, wherein said first strained layer is a compressively strained layer and said transistor device is a P-channel transistor.

6. The method of claim 1, wherein forming said nitride layer comprises performing a plasma enhanced atomic layer deposition process.

7. The method of claim 1, further comprising forming a second gate electrode on said substrate and forming a second strained layer over said second gate electrode, wherein the strain of said second strained layer is different in type from the strain of said first strained layer and wherein said first strained layer is formed over said second strained layer.

8. The method of claim 7, wherein said nitride layer is formed on said second strained layer.

9. The method of claim 7, wherein forming said second strained layer over said second gate electrode comprises forming said second strained layer over said first gate electrode and removing said second strained layer from above said first gate electrode.

10-19. (canceled)

20. A method for forming a transistor device, comprising
forming a first gate electrode above an upper surface of a substrate;
performing a plasma enhanced atomic layer deposition process to deposit a nitride layer over said first gate electrode and on and in contact with said upper surface of said substrate; and
forming a first strained silicon nitride layer on and in contact with an upper surface of said nitride layer.

21. The method of claim 20, wherein said nitride layer is a silicon nitride layer.

22. The method of claim 20, wherein said nitride layer has a thickness of less than 3 nm.

23. The method of claim 20, wherein said first strained silicon nitride layer is formed by performing a chemical vapor deposition process, said first strained silicon nitride layer is a compressively strained layer and said transistor device is a P-channel transistor.

24. The method of claim 20, wherein said first strained silicon nitride layer is formed by performing a chemical vapor deposition process, said first strained silicon nitride layer is a tensile strained layer and said transistor device is an N-channel transistor.

25. The method of claim 20, further comprising forming a second gate electrode above said upper surface of said substrate and forming a second strained silicon nitride layer over said second gate electrode, wherein the strain of said second strained silicon nitride layer is different in type from the strain of said first strained silicon nitride layer and wherein said first strained silicon nitride layer is formed over said second strained silicon nitride layer.

26. The method of claim 25, wherein said nitride layer is formed on and in contact with said second strained silicon nitride layer.

27. The method of claim 25, wherein forming said second strained silicon nitride layer over said second gate electrode comprises forming said second strained silicon nitride layer over said first gate electrode and removing said second strained silicon nitride layer from above said first gate electrode.

28. A method for forming a transistor device, comprising
forming a first gate electrode above an upper surface of a substrate;
performing a plasma enhanced atomic layer deposition process to conformably deposit a silicon nitride layer having a thickness of less than 3 nm over said first gate electrode and on and in contact with said upper surface of said substrate; and
performing a chemical vapor deposition process to form a first strained silicon nitride layer on and in contact with an upper surface of said silicon nitride layer.

29. The method of claim 28, further comprising forming a second gate electrode above said upper surface of said substrate and forming a second strained silicon nitride layer over said second gate electrode, wherein the strain of said second strained silicon nitride layer is different in type from the strain of said first strained silicon nitride layer and wherein said first strained silicon nitride layer is formed over said second strained silicon nitride layer.

30. The method of claim 29, wherein said silicon nitride layer is formed on and in contact with said second strained silicon nitride layer.

31. The method of claim 29, wherein forming said second strained silicon nitride layer over said second gate electrode comprises forming said second strained silicon nitride layer over said first gate electrode and removing said second strained silicon nitride layer from above said first gate electrode.
